(19) United States
(12) Patent Application Publication
(10) Pub. No.: US 2011/0095277 A1
(43) Pub. Date: Apr. 28, 2011

(54) ORGANIC ELECTRONIC DEVICES AND METHODS FOR MANUFACTURING THE SAME

(76) Inventor: Tilman BEIERLEIN, Thalwil (CH)

(21) Appl. No.: 12/909,985

(22) Filed: Oct. 22, 2010

Related U.S. Application Data
(60) Provisional application No. 61/272,694, filed on Oct. 22, 2009.

(51) Int. Cl. H01L 51/00

(52) U.S. Cl. 257/40; 438/99; 257/E51.001

(57) ABSTRACT

The present invention discloses a method for manufacturing an Organic-Electronic (OE) Device. The method comprises providing at least one lower electrode onto a substrate; providing at least one lower organic layer onto the lower electrode; providing at least one upper electrode onto the lower organic layer to obtain an OE stack; providing a glue, providing a cover, and dicing the OE stack into a plurality of OE dies, and providing a plurality of side-contact electrodes on at least one sidewall of the OE dies. A plurality of voltages is respectively applicable to the plurality of side-contacted electrodes such that the plurality of side-contacted electrodes become electrically connected over the at least one organic layer.

### CROSS-REFERENCE TO RELATED APPLICATIONS

This patent application claims priority from U.S. Provisional Application 61/272,694 filed on Oct. 22, 2009, the disclosure of which is incorporated herein by reference in its entirety.

### FIELD OF THE INVENTION

The present invention relates to organic electronic devices (OEDs) in general and in particular to organic light-emitting devices (OLEDs), organic field-effect transistors (OFETs), organic memory devices (OMEM) and organic photovoltaic devices (OPVDs).

### DESCRIPTION OF THE FIGURES

These and further features and advantages of the invention will become more clearly understood in the light of the ensuing description of the embodiments thereof, given by way of example only, with reference to the accompanying figures, wherein:

FIG. 1A is a schematic top view illustration of an OE stack comprising a substrate with the patterned lower electrode material provided thereon, according to an embodiment of the invention;

FIG. 1B is a schematic top view illustration of the stack of FIG. 1A further with a lower and an upper organic layer provided thereon, according to an embodiment of the invention;

FIG. 2A is a schematic top view illustration of the OE stack of FIG. 1B, further with the patterned upper electrode material provided thereon, according to an embodiment of the invention;

FIG. 3 is a schematic top view illustration of the OE stack of FIG. 2A, further comprising a cover provided on the OE stack, according to an embodiment of the invention;

FIG. 4A is a schematic cross-sectional side view illustration of the stack of FIG. 3 in a first orientation, according to an embodiment of the invention;

FIG. 4B is a schematic cross-sectional side view illustration of the OE stack of FIG. 3 in a second orientation rotated by 90 degrees with respect to the above-mentioned first orientation, according to an embodiment of the invention;

FIG. 5 is a schematic cross-sectional side view illustration of an OE stack separated into an upper stack part and a lower stack part, the OE stack comprising at least one patterned sacrificial layer, according to an embodiment of the invention;

FIG. 6 is a schematic cross-sectional side view illustration of the OE stack of FIG. 5, wherein the upper stack and lower stack part are merged, and wherein cutting lines are schematically indicated, according to an embodiment of the invention;

FIG. 7A is a schematic cross-sectional side view illustration of an OE die comprising the sacrificial layers, according to an embodiment of the invention;

FIG. 7B is a schematic cross-sectional side view illustration of an OE die, the sacrificial layers being removed therefrom according to an embodiment of the invention;

FIG. 7C is a schematic cross-sectional side view illustration of an Organic Electronic Device (OED) including a first and a second side-contact electrode;

FIG. 8A is a schematic cross-sectional side view illustration of an OE assembly, according to an embodiment of the invention;

FIG. 8B is a schematic cross-sectional side view illustration of an OE assembly, according to an alternative embodiment of the invention;

FIG. 9A is a schematic cross-sectional side view illustration of an OE assembly, according to another embodiment of the invention; and

FIG. 9B is a schematic cross-sectional side view illustration of an OE assembly, according to a yet other embodiment of the invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals and/or letters may be repeated among the figures to indicate identical or analogous elements but may not be referenced in the description for all figures.

### BACKGROUND OF THE INVENTION

Inorganic light-emitting diodes are light-emitting elements employed for small indicators and tiny signal lamps. Such inorganic light-emitting diodes are based on inorganic semiconductor materials such as Galliumarsenide (GaAs), Galliumphosphide (GaP), Galliumnitride (GaN), Indiumgalliumnitride (InGaN). These inorganic semiconductor materials are grown on crystalline substrates at high temperature. The resulting stack are then diced into pieces having edge sizes in the order of 100 μm, bonded to a conducting substrate constituting a lower electrode, and connected via wire-bond to a second electrode. In order to increase the emissive area of the die obtained thereby, diffusers and optics need to be added.

Compared to inorganic light emitting diodes, organic electric devices (OEDs) like organic light-emitting diodes (OLEDs) may provide larger emitting areas. OLED elements for displays and lighting elements are fabricated on glass substrates or polymeric substrates with a lateral dimension typically ranging from 25 mm to several hundreds of millimeters. In order to encapsulate the OLED elements, the substrate for the OLED elements and/or the cover glass is framed with adhesive. After providing the adhesive, the substrate and cover glass are merged together to obtain encapsulated OLED elements and are then diced to obtain individual encapsulated dices comprising a respective OLED element. In order to be able to provide electrical contacts on the substrate's surface, the OLED dices have a glass cover of smaller planar dimension than the corresponding substrate.

The following documents specify OLED structures and manufacturing processes.

U.S. Pat. No. 5,962,962 discloses a method of encapsulation for an organic electroluminescent (EL) device, which includes an inert liquid layer having a dissolved oxygen concentration of 1 ppm or less on the periphery of the organic EL device. More specifically, the disclosed electrode layers, i.e. anode and cathode, are structured to extend through the frame of the adhesive for contact outside the encapsulation glass which is smaller than the substrate.

U.S. Pat. No. 5,057,967 document discloses a rolled film capacitor comprising a pair of dielectric film strips piled one upon another and wound into a roll, each strip having a metal electrode pattern deposited on one surface thereof, the pattern including a number of rectangular island electrodes mutually separated by a plurality of lateral and longitudinal insulating gaps and regularly arrayed in both directions, the island electrodes mutually overlapping to form a number of small capacitor elements which are connected in series in both directions by shifting both strips one from another in both directions. A plurality of such capacitors can be aggregated to form an improved large capacitive power supply device.

Other OEDs such as organic field-effect transistors (OFETs) and organic photovoltaic devices (OPVDs) are encapsulated and electrically contacted in a way similar to OLEDs. Generally, the area needed to establish electrical contacts is rather large, typically on the order of 1-5 mm².

### DESCRIPTION OF THE INVENTION

It should be noted that the term “sidewall” as used herein refers to an OED surface or surfaces extending in the direction according to which layers of material of the OED are provided. In other words, the term “sidewall” refers to the surface defining the boundary of the planar expanse of a plurality of material layers forming the OED.

The terms “right”, “left”, “bottom”, “below”, “lower”, “top”, “above”, “elevated” and “upper” as well as grammatical variations thereof as used herein do not necessarily indicate that, for example, a “bottom” component is below a “top” component, or that a component that is “below” is indeed “below” another component or that a component that is “above” is indeed “above” another component as such directions, components or both may be flipped, rotated, moved in space, placed in a diagonal orientation or position, placed horizontally or vertically, or similarly modified. Accordingly, it will be appreciated that the terms “bottom”, “below”, “top” and “above” may be used herein for exemplary purposes only, to illustrate the relative positioning or placement of certain components, to indicate a first and a second component or to do both.

It should be noted that in respective embodiments of the invention, the term “determining” as used herein may refer to methods whose output may be an estimate of a parameter.

### SUMMARY OF THE INVENTION

The present invention discloses a method for manufacturing an Organic-Electronic Device (OED). The method comprises providing at least one lower electrode onto a substrate; providing at least one lower organic layer onto the lower electrode; providing at least one upper electrode onto the lower organic layer to obtain an OE stack; and dicing the OE stack into a plurality of OE dies.

In embodiments of the invention, the method comprises providing a plurality of side-contact electrodes, to at least one sidewall of an OE die. The plurality of side-contact electrodes are electrically disconnected from another such that said plurality of side-contact electrodes can be subjected to a prevailing voltage difference therebetween between.

In some embodiments of the invention, the method comprises providing a plurality of side-contact electrodes to a plurality of sidewalls of an OE die, respectively.

In embodiments of the invention, the method comprises providing a first and a second side-contact electrode respectively on at least one sidewall of at least one of the plurality of OE dies. Accordingly, the same sidewall may comprise a plurality of side-contact electrodes.

In some embodiments, the method comprises providing a first and a second side-contact electrode respectively on the first and second sidewall.

In embodiments of the invention, the first side-contact electrode is electrically coupled with the first lower electrode.

In embodiments of the invention, the second side-contact electrode is electrically coupled with the second lower electrode.

In embodiments of the invention, a first and a second voltage is respectively applicable to the first and the second side-contact electrode such that the lower and upper electrode become electrically connected over the at least one lower organic layer.

In embodiments of the invention, the method comprises providing a glue onto the upper electrode.

In embodiments of the invention, the method comprises providing a cover onto the upper electrode to obtain an OE stack.

In embodiments of the invention, the method comprises providing a sacrificial layer prior to dicing the OE stack.

In embodiments of the invention, the method comprises removing the sacrificial layer after dicing the OE stack into OE dies to obtain indentations.

In embodiments of the invention, the indentations increase the area of the sidewalls of the OE dies.

In embodiments of the invention, the method comprises providing the lower and the upper electrodes on the sidewalls with the increased contact area.

In embodiments of the invention, the method comprises providing the lower and the upper electrodes such that they engage and/or fill the indentations.

In embodiments of the invention, the method comprises providing a getter material onto the upper electrode material.

In embodiments of the invention, the method comprises the getter material absorbs impurities such as, for example, oxygen and/or moisture, to avoid degradation.

The present invention further disclose an Electronic Device (OED) comprising: a substrate; at least one lower electrode on the substrate; at least one organic layer, wherein the at least one lower electrode is embedded between the substrate and the at least one organic layer; and at least one upper electrode provided on the lower organic layer.

In embodiments of the invention, the OED comprises a first side-contact electrode; and a second side-contact electrode. The side-contact electrodes may be provided on at least one sidewall of the OED.

In embodiments of the invention, the first side-contact electrode and the second side-contact electrodes are provided on a first and a second sidewall of the OED.

In embodiments of the invention, the first and the second sidewall of the OED have one of the following orientations with respect to each other: the first sidewall is opposite to the second sidewall, or the first sidewall is adjacent and to the second sidewall and form an angle of at least approximately 90 degrees.

In embodiments of the invention, the side-contact electrodes are provided by employing vacuum deposition of metal or solution deposition of conductive ink and/or conductive paste.

In embodiments of the invention, the plurality of side-contact electrodes have a thickness that is ≦1 μm.

In embodiments of the invention, the OED may be embodied by at least one of the following devices: Organic light-emitting diode, an organic field-effect transistor, and an organic photovoltaic device.

In embodiments of the invention, the electrical contact area between the plurality of side-contact electrodes and the lower electrode material, as well as the electrical contact area between the plurality of side-contact electrodes and the upper electrode material, is the cross sectional area of the strips of the lower and upper electrode material.

The present invention further discloses an Organic Electronic (OE) Assembly comprising an OED according to an embodiment of the invention, wherein said OED is electrically coupled with a printed circuit board.

### DETAILED DESCRIPTION OF THE INVENTION

It is an objective of the underlying invention to teach alternative Organic Electric Devices (OEDs) that have an increased ratio between the coverage area of the active area and the total coverage area of the organic device (active-to-total area ratio), as well as methods of manufacturing such OEDs. More specifically, OEDs according to an embodiment of the invention comprise electrical side contacts. An OED may include, for example, an Organic Light-Emitting Diode (OLED), an Organic Field-Effect Transistor (OFET), an Organic Photovoltaic Device (OPVD), or any combination of the aforesaid. In embodiments of the invention, the OED may be may used for at least one of the following applications: a light source, a self-emitting indicators, pictograms, excitation sources for sensor applications.

A plurality of OEDs having increased active-to-total area ratio may be manufactured by employing wafer scale processes.

The employment of wafer scale processes includes the production of an OE stack which is then diced according to a predetermined dicing pattern into a plurality of OE dies. The employment of wafer scale processes for example enables the manufacturing of OE dies having lateral dimensions (in the x-y plane) of, for example, 50×50 mm², ≦0×10 mm².

According to an embodiment of the invention, the method of manufacturing an OED includes providing an OE die with electrical connections, which are embodied by electrically conductive materials. Methods of providing the OE die with electrically conductive material include (hereinafter: electrode layer), for example, at least one of the following processes: the evaporation of metal, spraying conductive ink, and spraying conductive paste. According to an embodiment of the invention, the electrically conductive material is provided on at least one sidewall of the OE die to make electrical contact with a lower and an upper electrode layer in a manner such that a voltage difference prevails between the lower and the upper electrode layer. As a result, the planar dimensions of the OE die and of the resulting OED are almost equal, wherein their difference in planar dimensions is defined by the thickness t_{electr} of the electrode layer provided. More specifically, if the planar dimensions of an OE die is defined by the mathematical term L_{dice}×W_{dice}, then the planar dimensions of the corresponding OED may be described by the mathematical term (L_{dice}+t_{electr})×W_{dice} or (L_{dice}+2×t_{electr})×W_{dice}, for an OED with one or two electrode layers, respectively.

TABLE 1 below exemplifies ranges of measures of electrode layers:

| | First Option of | Second Option of | Third Option of |
|---|---|---|---|
| | Ranges | Ranges | Ranges |
| Thickness of | 3 nm-10 μm | 10 nm-1 μm | 10 nm-200 nm |
| Electrode Layers | | | |
| Width of Electrode | 0.5 μm-20 mm | 5 μm-10 mm | 50 μm-5 mm |
| Layers | | | |

According to an embodiment of the invention, an OED with increased active-to-total area ratio may be manufactured individually according to an embodiment of the invention.

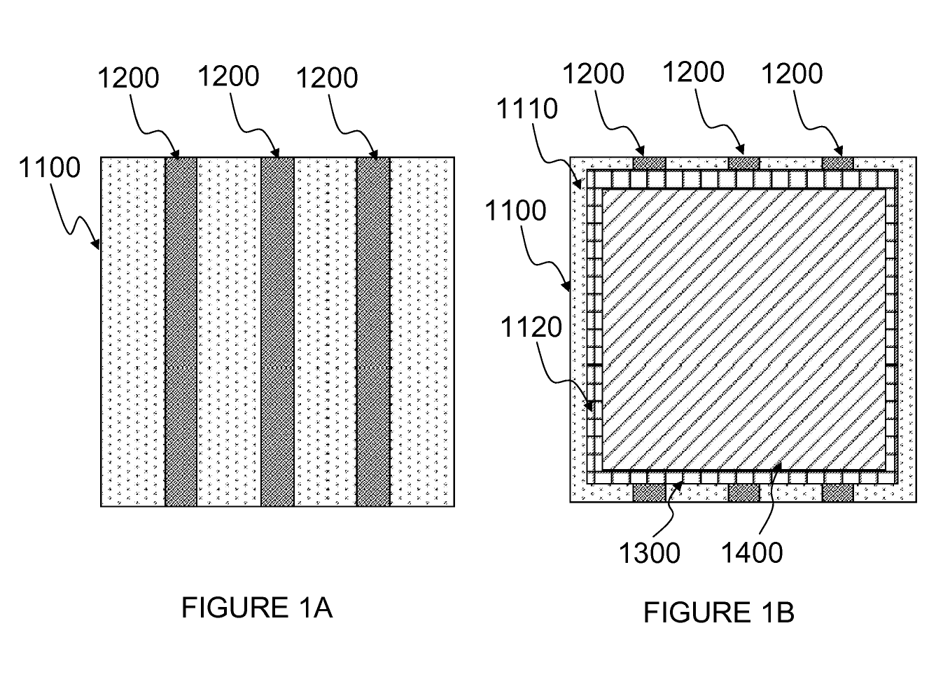

Reference is now made to FIG. 1A. The method for manufacturing an OED like, e.g., an OLED, may include the procedure of providing a substrate 1100 with a lower electrode material, e.g., by coating. For example, a lower electrode material 1200 may be provided in the form of a plurality of stripes. The plurality of lower stripes of lower electrode material 1200 may be provided such to extend over the entire surface of substrate 1100 and in a patterned manner to be arranged at least approximately in parallel with respect to each other. The plurality of lower stripes of lower electrode material 1200 may be equidistantly arranged with respect to each other.

Further reference is now made to FIG. 1B. According to an embodiment of the invention, at least one organic layer is then provided, e.g., by deposition on top of the first plurality of strips of the electrode material and the substrate. The at least one organic layer may for example be embodied by a layer of light emitting cells (LECs). For example, a lower organic layer 1300 and an upper organic layer 1400 are then provided, e.g., by deposition, on top of the plurality of strips of lower electrode material 1200 and substrate 1100. In embodiment of the invention, the lower organic layer 1300 and upper organic layer 1400 may be provided such to cover substrate 1100 and first stripes of lower electrode material 1200 entirely. Alternatively, lower organic layer 1300 and upper organic layer 1400 may be provided such to cover substrate 1100 and first strips of electrode layer partially leaving out a first rim 1110 along the edge of substrate 1100. In some embodiments, circumferential first rim 1110 and/or a second rim 1120 may be of uniform width on all sides of substrate 1100. Alternatively, opposite sides of first rim 1110 and/or second rim 1120 may have different widths.

In some embodiments, the length and width of upper organic layer 1400 may be shorter than the length and width of lower organic layer 1300, therefore partially leaving out a second rim 1120 between lower organic layer 1300 and upper organic layer 1400.

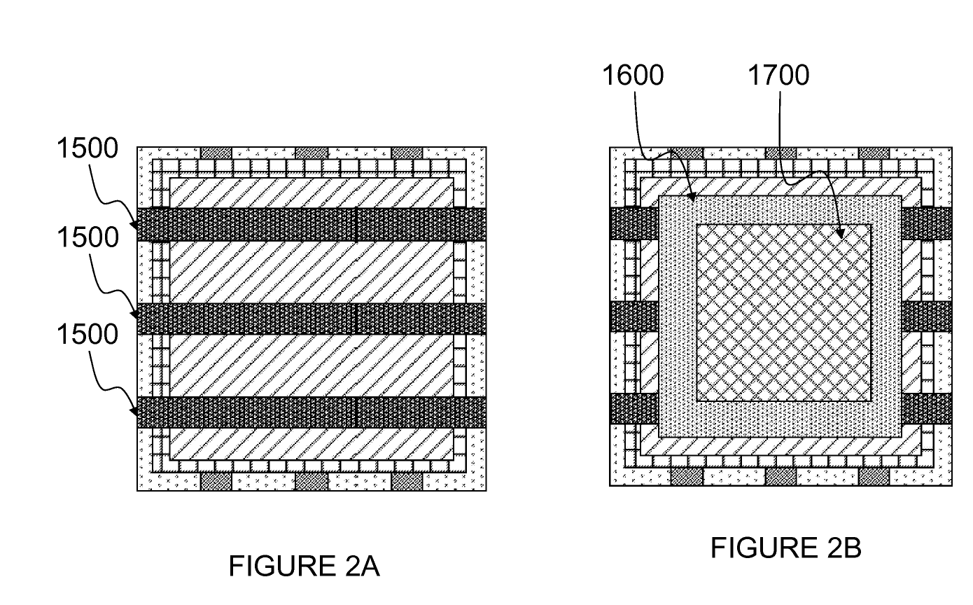

Additional reference is now made to FIG. 2A. The method of manufacturing an OED according to an embodiment of the invention may then include the step of providing (e.g., by deposition) an upper electrode material on top of the at least one organic layer. For example, upper electrode material 1500 may be provided in a patterned manner onto upper organic layer 1400. In an embodiment of the invention, upper electrode material 1500 may be provided to form a plurality of at least approximately parallel stripes, which may be equidistantly arranged with respect to each other. Moreover, the plurality of strips of upper electrode material 1500 may be rotated by an angle of at least approximately θ=90°. Otherwise stated, the plurality of parallel strips of upper electrode material 1500 may be perpendicularly oriented with respect to the plurality of strips of lower electrode material 1200. Upper electrode material 1500 may be provided to be in symmetry with the boundaries of substrate 1100.

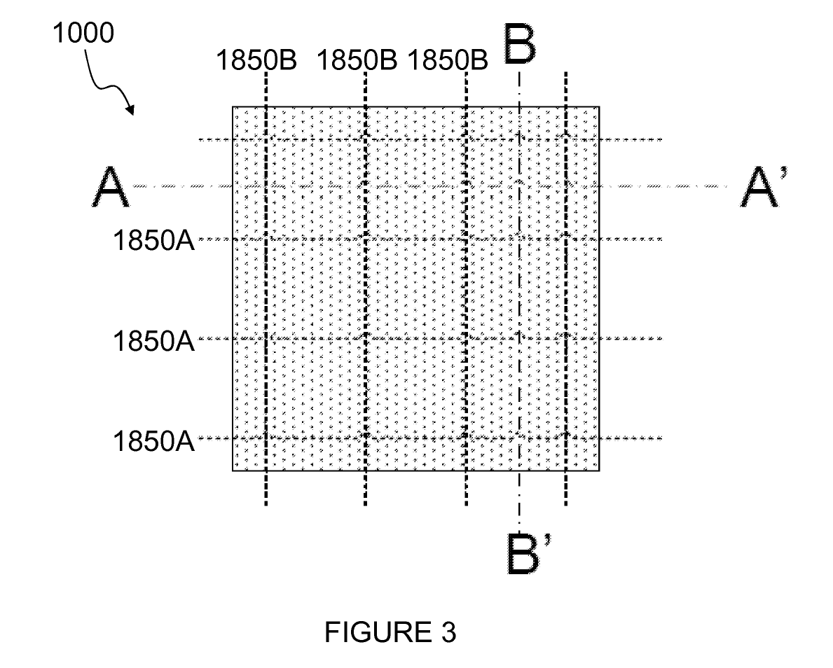

Additional reference is now made to FIGS. 2B and 3. The method of manufacturing an OED device may include in some embodiments of the invention the step of providing a getter material 1600 (FIG. 2B) onto upper organic layer 1400, and upper electrode material 1500. Getter material 1600 may be provided in a manner to cover upper organic layer 1400 (and therefore upper electrode material 1500) only partially, and optionally in a manner to be in symmetry with the boundaries of substrate 1100. Further, glue 1700 may then be dispensed (FIG. 2B) to glue or laminate thereon a cover 1800 (FIG. 3) for protection of the elements of OED 1001 between substrate 1100 and cover 1800, for example, from moisture. Cover 1800 may be provided such to cover the entirety of the lateral dimensions of substrate 1100 to finalize an OE stack 1000.

After hardening of glue 1700, OE stack 1000 is then cut along horizontal and vertical cutting lines 1850A and 1850B into OE dies having dimensions of, for example, 7×7 mm. The method of cutting may be realized, for example, by employing at least one of the following techniques: scribe-and-break; sawing; and laser cutting.

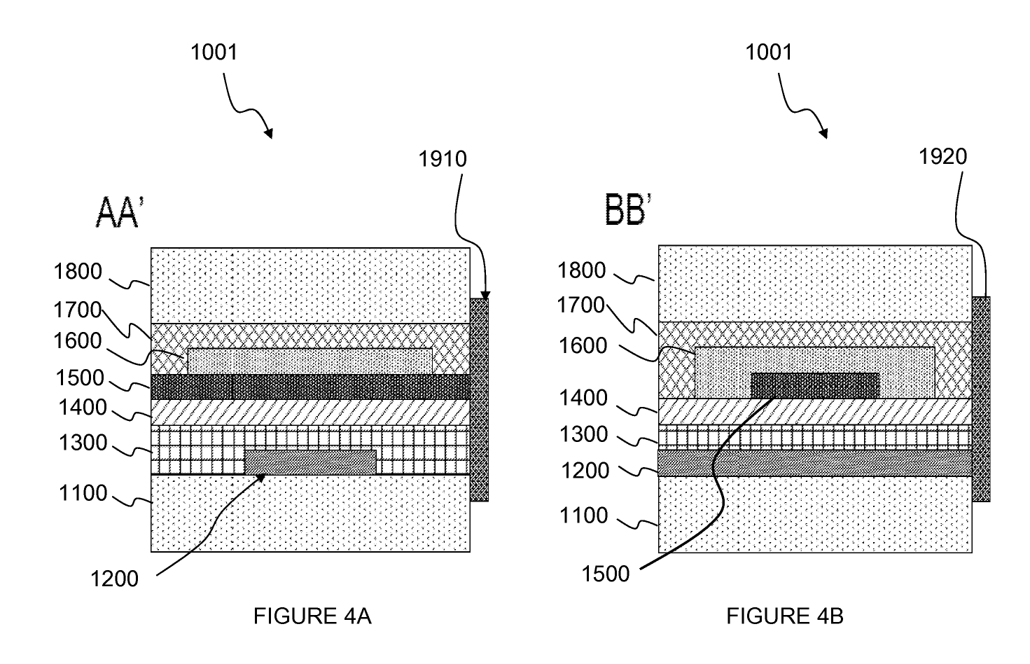

Reference is now made to FIGS. 4A and 4B, which schematically illustrates cross-sectional side view illustrations of OE die 1000 along line A-A′ and B-B′, respectively, together with a side-contact electrode, as outlined herein below in greater detail. An OE die comprising a side-contact electrode is hereinafter referred to as a “OE device”. More specifically, an OED 1001 includes a first side-contact electrode 1910 that is provided sideways, i.e., on at least some part of the sidewall of OED 1001 such to make electrical contact with upper electrode material 1500 at least. First side-contact electrode 1910 may be deposited such to cover a first sidewall of OED 1001 entirely, or may be provided in a patterned manner such to correspondingly cover the first sidewall of OED 1001 only partially. Similarly, an electrical contact may be established between a second side-contact electrode 1920 and lower electrode material 1200 by providing second side-contact electrode 1920 on a second sidewall of OE die 1000, wherein first sidewall and second sidewall may for example to a pair of sidewalls that are opposite to one another or to two a pair of sidewalls that are adjacent to one another at an angle of at least approximately 90 degrees. As a result thereof, lower electrode material 1200 and upper electrode material 1500 are indirectly electrically coupled with each other due to the voltage difference between first side-contact electrode 1910 and second side-contact electrode 1920. More specifically, according to an embodiment of the invention, lower electrode material 1200 and upper electrode material 1500 are subjected to a voltage difference by first side-contact electrode 1910 and second side-contact electrode 1920, respectively. The area wherein lower electrode material 1200 and upper electrode material 1500 are overlapping is the active area of OED 1001, since upon applying a corresponding emission voltage, there is a flux of charges through said active area from lower electrode material 1200 to upper electrode material 1500, or vice versa, depending on the direction of the voltage. As a result of the application of the emission voltage at lower electrode material 1200 and upper electrode material 1500, light is emitted from OED 1001. The operating voltage of an OED according to an embodiment of the invention may range, for example, from 4 to 6 Volts, or in some embodiments, be up to 230 V.

For bottom-emitting OEDs, substrate 1100 may be made of substantially transparent material such as, for example, glass, sapphire, plastic substrates (e.g., PE, PET, PEN, PP), or any other suitable material or combination of materials. The thickness of substrate 1100 may range, for example, from 100 μm to 2 mm.

In an embodiment wherein the structure of the OED is operative to be light emitting through the top or light-harvesting from the top, then substrate 1100 may be made of an opaque material. Correspondingly, cover 1800 is the preferably be made of a transparent material such as, for example, glass, sapphire, plastic substrates (e.g., PE, PET, PEN, PP), and the like.

Lower electrode material 1200 and/or upper electrode material 1500 are made of transparent or semi-transparent conductive material.

Whether lower electrode material 1200 and/or upper electrode material 1500 employed is transparent or semi-transparent depends on whether the OED is bottom-excited/emitting or top-excited/emitting. For bottom-excited/emitting electrodes, at least lower electrode material 1200 is (semi-)transparent and conductive, whereas for top-excited/emitting OEDs, upper electrode material 1500 is (semi-)transparent and conductive.

In an embodiment wherein the OED is bottom-emitting or bottom-excited, lower electrode material 1200 can be made of transparent oxides such as, for example, Indium-Tin-Oxide (ITO), Indium-Zinc-Oxide (IZO), Aluminum-Indium-Oxide (ATO), or any other suitable material. The thickness of lower electrode material 1200 may range for example, from 10 nm to 200 nm. Further, OEDs according to embodiments of the invention that are bottom-emitting or bottom-excited, or non-optical OEDs, upper electrode material 1500 may be made of electrode materials such as, for example, Al, Ni, Au, and the like.

Analogously, in an embodiment wherein the OED is top-emitting or top-excited, upper electrode material 1500 can be made of transparent oxides such as, for example, Indium-Tin-Oxide (ITO), Indium-Zinc-Oxide (IZO), Aluminum-Indium-Oxide (ATO), or any other suitable material, and the thickness of upper electrode material 1500 may range for example, from 10 nm to 200 nm. In OEDs according to embodiments of the invention that are of top-emitting or top-excited, or non-optical OEDs, lower electrode material 1200 may be made of electrode materials such as, for example, Al, Ni, Au, and the like.

In some embodiments, of the invention, lower electrode material 1200 and/or upper electrode material 1500 may be embodied by metal electrodes that are (semi-) transparent and conductive, for respective bottom- or top-emitting OEDs. The metal electrodes that may be employed have a thickness which is larger than the percolation threshold but still thin enough to possess an absorbance of, for example, ≦1 optical density (OD), ≦0.5 OD, or ≦0.25 OD.

As already briefly discussed hereinabove, an OED according to an embodiment of the invention includes at least one organic layer. Accordingly, OED 1001 exemplified herein as to include a plurality, or more specifically, two organic layers (lower organic layer 1300 and upper organic layer 1400) shall not be construed as limiting. Therefore, an OED according to an embodiment of the invention may include a single layer of organic layer or, alternatively, at least three layers comprising at least organic layer and optionally inorganic layer, as outlined herein below in more detail. An OED embodying for example of polymer-based light-emitting diode (LED) may include a hole injection layer (e.g. Poly(3,4-ethylenedioxythiophene) or PEDOT) and a layer of a light-emitting polymer (LEP). The hole injection layer and/or the LEP may respectively have a thickness ranging, for example, from 200 nm down to 0.5 nm. Accordingly, the hole injection layer and/or the LEP layer may have a thickness of, for example, at least approximately 80 nm. Methods of depositing layers of organic or inorganic layer include, for example, at least one of the following: spin-coating, printing in general (e.g. via ink-jet, gravure, screen printing etc.), and vacuum coating (e.g. evaporation, plasma polymerization, sputtering, etc.).

In an embodiment of the invention, upper electrode material 1500 may be embodied by a stack of metal layers for carrier injection. In OEDs embodying, for example, OLEDs or OPDs, the metal layers may be made of low work function metals such as, for example, like, Ba, Ca, Li covered with an Ag or Al layer. Methods for providing upper electrode material 1500 may include, e.g., at least one of the following processes: ink-jet printing, gravure printing, and screen-printing or vacuum coating.

Employing getter material 1600 may extend the lifetime of an encapsulated OED Getter material 1600 may be made of, for example, barium, barium-oxide, calcium, calcium oxide, or any other material or combination of materials suitable to absorb impurities such as water and/or oxygen for example. Methods of providing getter material 1600 may include at least one of the following manufacturing processes: dispensing, printing, and other coating processes. The thickness of getter layer 1600 may range, for example, from 100 nm to a few micrometers such as 10 micrometers.

Glue 1700 may be embodied, for example, by at least one of the following materials: UV-curable, thermal-curable, and two-component epoxies. The thickness of glue 1700 may range, for example, between 1 to 80 micrometers.

Cover 1800 may be made of any suitable material such as, for example, glass, or plastic with sufficient barrier properties. Cover 1800 may have a thickness ranging, for example, from 25 μm to 1 mm.

First side-contact electrode 1910 and second side-contact electrode 1920 are made of materials suitable for establishing reliable contact with lower electrode 1200 and upper electrode 1500. First side-contact electrode 1910 and/or second side-contact electrode 1920 may by provided e.g. by application (e.g., with a paint-brush) of conductive inks (e.g., silver ink); by evaporation of metals; or the sputtering of metals. Conductive inks can be applied e.g. by spraying or tampon-printing. The thickness of first side-contact electrode 1910 and/or second side-contact electrode 1920 embodied by conductive inks may, for example, range from 1 to 100 μm. The thickness of first side-contact electrode 1910 and/or second side-contact electrode 1920 embodied by sputtered or evaporated metals may range, for example, from 50 nm to 1 μm.

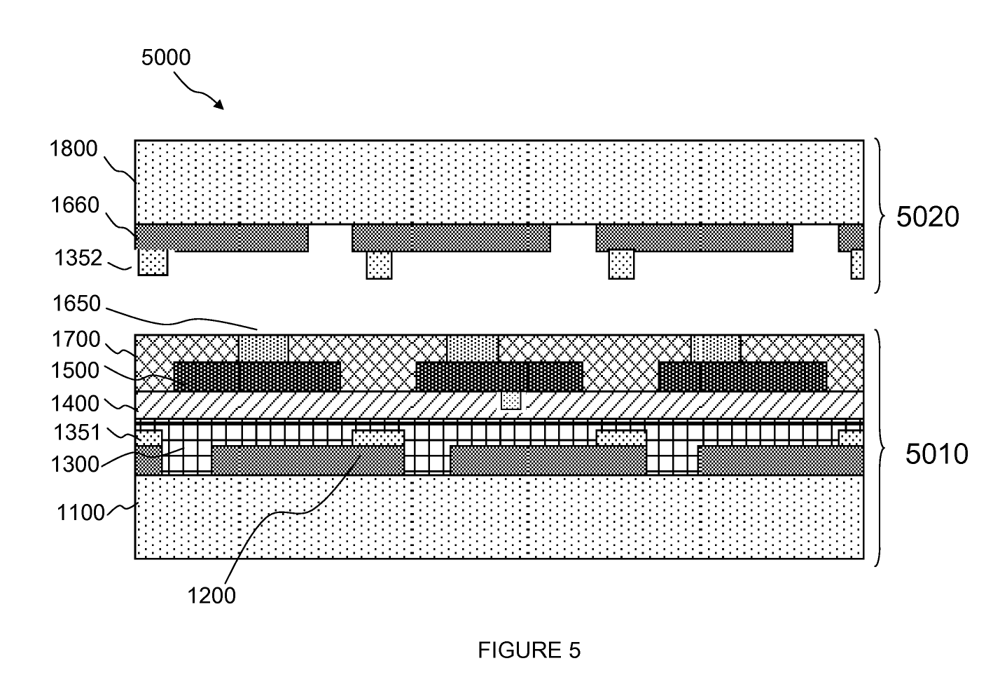

Additional reference is now made to FIG. 5. According to an embodiment of the invention, the method of manufacturing an OED comprises providing a sacrificial layer to obtain an OE die comprising an indentation at its sidewall increasing the contact area between a side-contact electrode and the sidewall of the OE die. More specifically, the side-contact electrodes engage with and fill said indentations. As a result of the increased contact area, the stability of the contact between the sidewall of the OE die and the side-contact electrode is increased, inter alia, due to increased friction between the OE die and the side-contact electrode.

It should be noted that the term “embedded” as used herein also encompasses the meaning “partially embedded”. Accordingly, a sacrificial layer may in some embodiments be fully embedded by solid-state material, and in some embodiments, a sacrificial layer may be only be partially embedded by solid-state material such that some parts of the same sacrificial layer may be for example be in contact with ambient air during the process of manufacturing.

According to an embodiment of the invention, an OE stack 5000 for example, is manufactured such to additionally include a lower sacrificial layer 1351, which may be provided, for example, in a manner such to be embedded between lower electrode material 1200 and lower organic layer 1300. Additionally or alternative, an OE stack 5000 may be manufactured such to include an upper sacrificial layer 1352 which may, for example, be embedded between glue 1700 and a patterned conductive layer 1660.

More specifically, lower sacrificial layer 1351 may be provided in a patterned manner directly on top of patterned lower electrode material 1200. Lower organic layer 1300, upper organic layer 1400 and upper electrode material 1500 may subsequently provided, e.g., as outlined hereinabove with respect to OE stack 1000.

In an embodiment of the invention, the method may then additionally include the step of providing a conductive material 1650 onto upper electrode material 1500, whereafter glue 1700 may be deposited.

According to an embodiment of the invention, on lower surface of cover 1800, patterned conductive layer 1660 may be provided. Further, upper sacrificial layer 1352 may be provided on the lower surface of patterned conductive layer 1660. Cover 1800, patterned conductive layer 1660 and upper sacrificial layer 1352 are hereinafter referred to as “upper stack part” 5020. The lower layers of OE stack 5000 are accordingly herein referred to as “lower stack part” 5010.

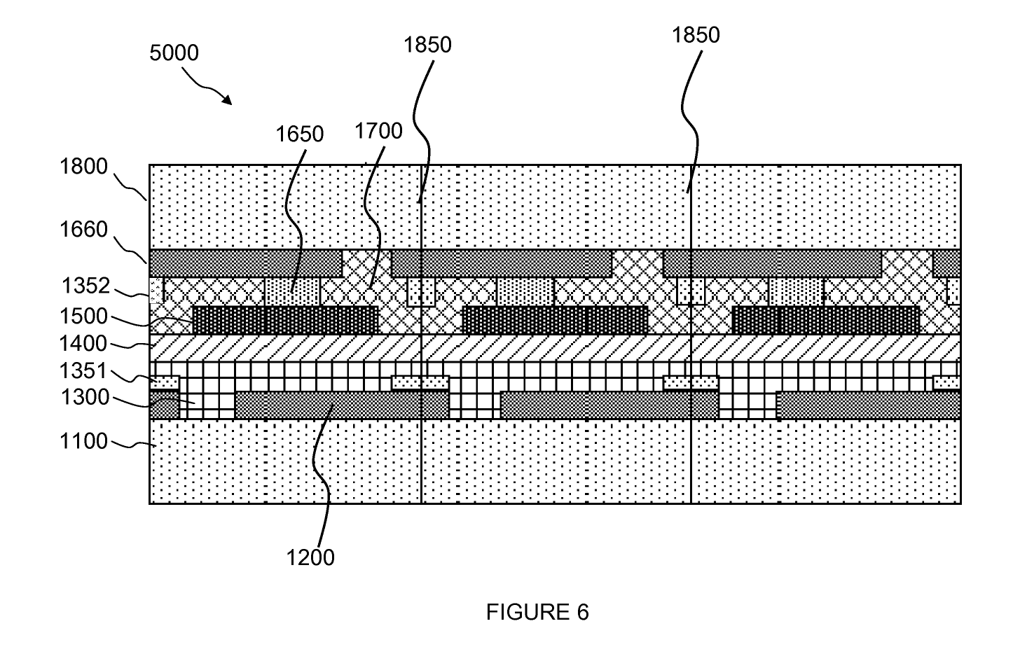

Additional reference is now made to FIG. 6, 7A, 7B and 7C.

As outlined in greater detail below, an OED according to an embodiment of the invention may be devised such to include a horizontal electrode layer or layers extending to the left and right sidewalls of the OED. However, these horizontal electrode layer(s) are disconnected resulting in horizontal left electrode and right electrode portions which are electrically separated from one another. Otherwise side-contact electrodes contacts would directly short-circuit the different horizontal electrode layers. Such an electrode layer that comprises a left electrode portion and a right electrode portion are hereinafter referred to as “patterned lower/higher electrode material” or “patterned conductive layer”.

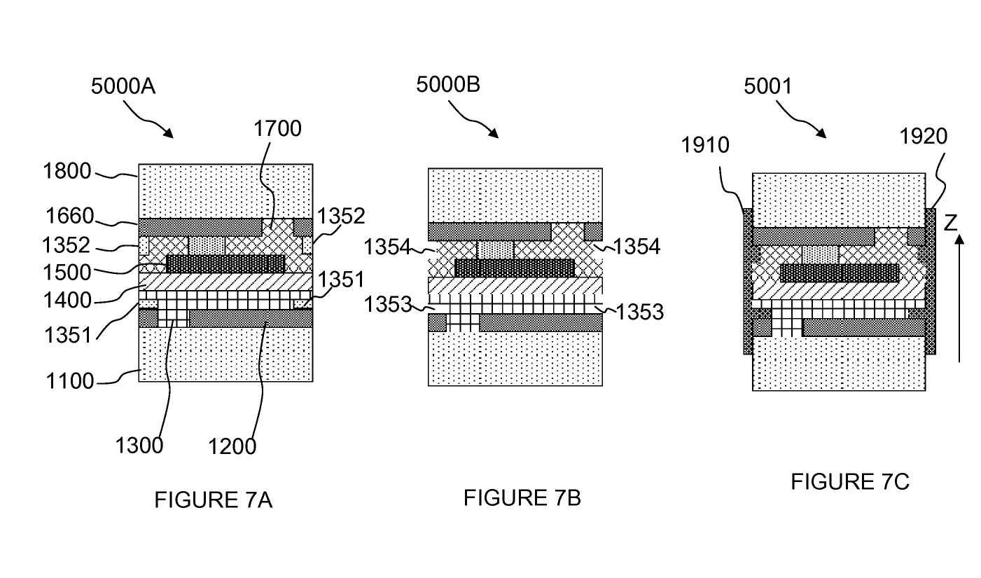

The method of manufacturing an OE stack such as, for example, OE stack 5000 includes merging upper stack part 5020 with lower stack part 5010 such that conductive material 1650 and patterned conductive layer 1660 come into electrical contact and such that upper sacrificial layer 1352 is embedded by glue 1700 and patterned conductive layer 1660. The resulting OE stack 5000 is then diced into individual OE dies 5000A (FIG. 7A) along cutting lines 1850 which run through lower sacrificial layers 1351 and upper sacrificial layer 1352.

As schematically illustrated in FIG. 7B, lower sacrificial layer 1351 and upper sacrificial layer 1352 are then removed. The two sidewalls of the resulting OE die 5000B may thus each comprise lower indentations 1353 and an upper indentations 1354.

As is schematically illustrated in FIG. 7C, side-contact electrodes 1910 and 1920 are then deposited on the sidewalls such to at least partially cover the latter. More specifically, first side-contact electrode 1910 is provided on one side of OE die 5000B such to fill both lower indentations 1353 and upper indentations 1354 and such to be at least in contact with patterned lower electrode material 1200 and upper electrode material 1500. Analogously, second side-contact electrode 1920 is provided on the other side of OE die 5000B such to fill both lower indentations 1353 and upper indentations 1354 and such to be at least in contact with patterned lower electrode material 1200 and upper electrode material 1500. The increase in contact area between any of the electrode materials and the sidewalls of OE die 5000B correspondingly increases the adhesiveness of the electrode materials with the sidewalls. Moreover, electrical contact with conductive layer 1660 may not only be made with the front face of conductive layer 1660, but also with the lower surface of conductive layer 1660. Analogously, electrical contact with patterned lower electrode material 1200 may not only be made with the front face of patterned lower electrode material 1200, but also with the upper surface of patterned lower electrode material 1200. As a consequence, a comparably more stable electrical contact can be made between conductive layer 1660 and wire bonds or side-contact electrodes, as well as a comparably more stable electrical contact can be made between patterned lower electrode material 1200 and wire bonds or side-contact electrodes.

According to an embodiment of the invention, lower sacrificial layer 1351 and upper sacrificial layer 1352 may be made of an (relatively easily) patternable material such as, for example, a photo-resist via lithography, removable and removed by appropriate solvents such as, for example, aceton, propanol, or the like. Clearly, glue 1700 needs to be resistant to these solvents in order to avoid removal of glue 1700 when subjecting OE die 5000B to solvents.

According to an embodiment of the invention, conductive material 1650 may be embodied, for example, by metal paste (e.g., a silver paste) that is deformable such to enable electrical coupling of conductive material 1650 with patterned conductive layer 1660. Patterned conductive layer 1660 may be made of, for example, ITO, Al, Ni, or any suitable electrically conductive material.

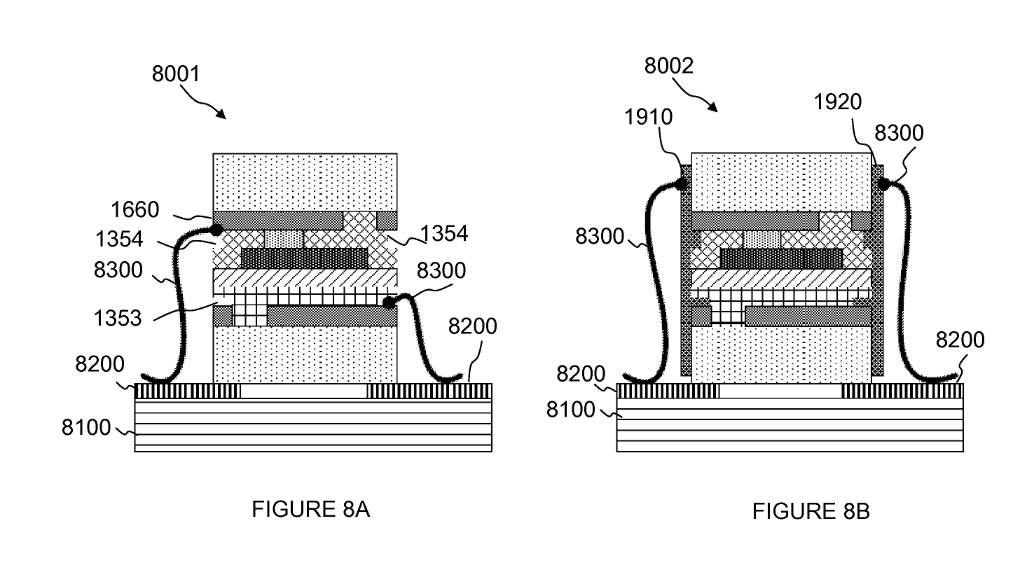

Further reference is now made to FIG. 8A, 8B, 9A and 9B. An OE assembly 8001 according to an embodiment of the invention includes an OE die mounted and electrically coupled with conducting paths 8200 of a printed circuit board 8100. Conducting paths 8200 are electrically coupled to external circuitry (not shown). Accordingly, the OE die is electrically coupled with the external circuitry.

As is for example schematically illustrated in FIG. 8A, an OE die such as, for example, OE die 5000B, may be electrically coupled with conducting paths 8200, for example, via wire bonds 8300 directly over patterned lower electrode material 1200 and patterned conductive layer 1660 of OE die 5001.

Alternatively, as is for example schematically illustrated in FIG. 8B, an OE die such as, for example, OE die 5001, first side-contact electrode 1910 and second side-contact electrode 1920 are electrically coupled with conducting paths 8200 via wire bonds 8300, wherein the angle between the contact surface of conducting paths 8200 and the contact surface of side-contact electrodes 1910 and 1920 is at least approximately 90 degrees.

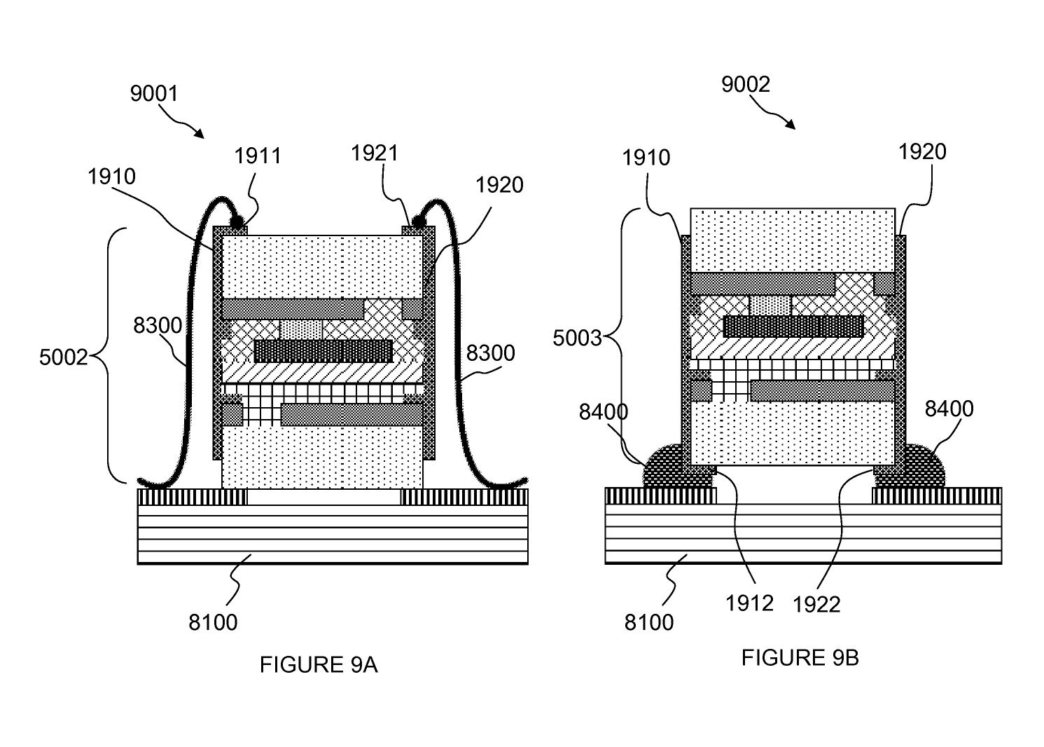

According to an alternative embodiment of the invention, as is schematically illustrated in FIG. 9A, in a OE die such as, for example, OE die 5002, first side-contact electrode 1910 and/or second side-contact electrode 1920 may be provided onto OE die 5000B such to extend from the at least approximately vertical sidewalls of OE die 5000B, across its edges to the top of at least approximately horizontal upper surface of cover 1800, and extend inwardly. First side-contact electrode 1910 and second side-contact electrode 1920 therefore comprises a first upper horizontal extension 1911 and a second upper horizontal extension 1921. Thus, the contact area between side-contact electrodes 1910 and 1920 to the OE die is further increased. Correspondingly, first end of wire bonds 8300 may be electrically coupled with first horizontal upper extension 1911 and/or second horizontal upper extension 1921 of side-contact electrodes 1910 and/or 1920, respectively. The corresponding second end of wire bonds 8300 are electrically coupled with conducting paths 8200. As a result, OE die 5002 is electrically coupled with printed circuit board 8100 to form an OE assembly 9001.

Additional reference is now made to FIG. 9B. In some embodiments of the invention an OE assembly such as, for example, OE assembly 9002, may include an OE die such as, for example, OE die 5003, which may include side-contact electrodes 1910 and 1920 each extending over the lower opposite edges of OE die 5003 from the at least approximately vertical and opposite sidewalls of OE die 5003 horizontally and inwardly along the lower surface of substrate 1100. First side-contact electrode 1910 and second side-contact electrode may thus have a first lower horizontal extension 1912 and a second lower horizontal extension 1922. Thus, the contact area between side-contact electrode 1910 and 1920 to the OE die is further increased. OE die 5003 may be electrically coupled with conductive paths 8200 via conductive connections 8400. Conductive connections 8400 may be provided before or after positioning OE die 5003 on printed circuit board 8100. Conductive connections 8400 may for example be made of Ag-ink, Ag-paste or a solder paste, e.g., as used in the art in a standard reflow soldering process.

The following, a method of manufacturing an OE stack is exemplified. For example, a substrate 1100 made, e.g., glass and having the size of e.g., the size 2″×2″ and of, e.g., 0.7 mm thickness, may be coated with patterned lower electrode material 1200 made, of, e.g., ITO, with a thickness of, e.g., 150 nm. Patterned lower electrode material 1200 may then be patterned by employing, e.g., photolithography and wet-etching, into at least approximately parallel strips having a width of, e.g., 2 mm and a grid period of, e.g., 4 mm. Substrate 1100 may then for example be plasma treated in a vacuum reactor. Lower organic layer 1300 of, e.g., a polymer (PEDOT, AL4083 from H.C. Starck) may then be deposited on substrate 1100, e.g., via spin-coating and dried on a hot plate at a temperature of for example 200° C. for, e.g., 10 minutes which may result in a layer thickness of the organic layer of about 70 nm for example. Upper organic layer 1400 made, for example, of light-emitting polymer (e.g. PDY132 form Merck) may then be deposited by employing, e.g., spin-coating (at a speed of, e.g., 1500 rpm) and baked on a hotplate at a temperature of, e.g., 80° C., for, e.g., 10 minutes which results in a thickness of for example, about 70 nm. Upper electrode material 1500 made of a bilayer for example Barium (having a thickness of, e.g., 5 nm) and Aluminum with a thickness of e.g., 70 nm may then be successively evaporated on top of lower organic layer 1300 through a shadow mask to create at least approximately parallel patterned strips of upper electrode material 1500. These strips of upper electrode material 1500 may for example have a width of, e.g., 2 mm and grid period of, e.g., 4 mm. The strips of upper electrode material 1500 may be patterned such to be perpendicular to the strips of patterned lower electrode material 1200. The stack below and including upper electrode material 1500 is hereinafter referred to as “organic stack”.

Under inert-gas (e.g., N2) glovebox, glue 1700 made, of, e.g., an UV-curable epoxy (e.g. DELO LP651) may then be deposited on top of a cover 1800 made of, e.g., glass having a size of, e.g., size 2″×2″. This cover glass is placed with the glue-side on top of the organic stack. Glue 1700 may then be cured via intense UV-light, to obtain an OE stack. The obtained OE stack having dimensions of e.g., 2″×2″, is diced into OE dies, each die having dimension of, e.g., 4 mm×4 mm. The OE dies are then provided with first side-contact electrode 1910 and second side-contact electrode 1920 which may be embodied, for example, by conductive silver ink (e.g. Ferro GmbH), e.g., with a paintbrush. The OED is thus actually finalized. For further encapsulation of the active material, the edges of the OE dies can be additionally covered with a special barrier layer which may for example be made of SiOₓ, SiN_{X}, parylene or organic-inorganic multilayers.

It will be appreciated by persons skilled in the art that the disclosed invention is not limited to what has been particularly shown and described hereinabove.

What is claimed is:

1. A method for manufacturing an Organic-Electronic Device (OED), said method comprising:
a) providing at least one lower electrode onto a substrate;
b) providing at least one lower organic layer onto said lower electrode;
c) providing at least one upper electrode onto said lower organic layer to obtain an OE stack;
d) dicing said OE stack into a plurality of OE dies;
wherein said method further comprises:
providing a plurality of side-contact electrodes on at least one sidewall of at least one of said plurality of OE dies,
wherein at least one first of said plurality of side-contact electrodes is electrically coupled with said at least one first lower electrode;
wherein at least one second of said plurality of side-contact electrodes is electrically coupled with said at least one second lower electrode; and
wherein a plurality of voltages are respectively applicable to said plurality of side-contact electrodes such that said at least one lower and at least one upper electrode become electrically connected over said at least one lower organic layer.

2. The method for manufacturing the OED according to claim 1, said method further comprising:
a) providing a glue onto said upper electrode; and
b) providing a cover onto said upper electrode to obtain an OE stack.

3. The method for manufacturing the OED according to claim 1, said method comprising:
providing a sacrificial layer prior to dicing said OE stack; and
removing said sacrificial layer after dicing said OE stack into OE dies to obtain indentations, wherein said indentations increase the area of the sidewalls of said OE dies; and
providing said lower and said upper electrodes on said sidewalls with said increased contact area.

4. The method for manufacturing the OED according to claim 1, said method comprising providing a getter material onto said upper electrode material, said getter material absorbing impurities.

5. A Organic Electronic Device (OED) comprising:
a substrate;
at least one lower electrode on said substrate;
at least one organic layer, wherein said at least one lower electrode is embedded between said substrate and said at least one organic layer;
at least one upper electrode provided on said lower organic layer;
wherein said OED further comprises:
a first side-contact electrode; and
a second side-contact electrode,
wherein said first side-contact electrode and said second side-contact electrodes are provided on at least one sidewall of said OED.

6. A Organic Electronic Device (OED) according to claim 5
wherein said first side-contact electrode and said second side-contact electrodes are provided on a first and a second sidewall of said OED,
wherein said first and said second sidewall of said OED have one of the following orientations with respect to each other:
said first sidewall is opposite to said second sidewall, or
said first sidewall is adjacent and to said second sidewall and form an angle of at least approximately 90 degrees.

7. The OED according to claim 5, wherein said plurality of side-contact electrodes has a thickness of ≦1 micrometer.

8. The OED according to claim 5, wherein the electrical contact area between said plurality of side-contact electrodes and said lower electrode material, as well as the electrical contact area between said plurality of side-contact electrodes and said upper electrode material, is the cross-sectional area of the strips of said lower and upper electrode material.

9. A Organic Electronic (OE) Assembly comprising:
a substrate;
at least one lower electrode on said substrate;
at least one organic layer, wherein said at least one lower electrode is embedded between said substrate and said at least one organic layer;
at least one upper electrode provided on said lower organic layer;
wherein said OED further comprises:
a first side-contact electrode; and
a second side-contact electrode,
wherein said first side-contact electrode and said second side-contact electrodes are provided on a first and a second sidewall of said OED,
wherein said first and said second sidewall of said OED have one of the following orientations with respect to each other:
said first sidewall is opposite to said second sidewall, or
said first sidewall is adjacent and to said second sidewall and form an angle of at least approximately 90 degrees; and
a printed circuit board comprising conductive paths;
wherein said OED is electrically coupled with said printed circuit board.
